(19) United States
(12) Patent Application Publication
(10) Pub. No.: US 2023/0010890 A1
(43) Pub. Date: Jan. 12, 2023

(54) LASER TEMPERATURE STABILISATION

(71) Applicant: PERKINELMER SINGAPORE PTE. LTD., Singapore (SG)

(72) Inventor: Ben PERSTON, Beaconsfield, Bucks (GB)

(21) Appl. No.: 17/780,335

(22) PCT Filed: Nov. 26, 2020
(86) PCT No.: PCT/GB2020/053023

§ 371 Date: May 26, 2022

(30) Foreign Application Priority Data
Nov. 27, 2019 (GB) 1917273.3

(51) Int. Cl. H01S 5/06; H01S 5/068; G01J 3/10; G01J 3/44

(52) U.S. Cl. CPC H01S 5/0612; H01S 5/068; H01S 5/0617; G01J 3/10; G01J 3/44

(57) ABSTRACT

A system comprising a laser 1001 for illuminating a sample S under investigation, a temperature sensor 1019 for sensing the operating temperature of the laser 1001 and generating an output which is indicative of the sensed temperature, a temperature stabilisation device 1018 for controlling the operating temperature of the laser 1001, and a controller 1012 for determining a target operating temperature or temperature range for the laser based on the output of the temperature sensor 1019 and for controlling the temperature stabilisation device 1018 to drive the operating temperature of the laser 1001 towards the target operating temperature or temperature range.

### TECHNICAL FIELD

Aspects of the present application relate to laser temperature stabilisation techniques. Some aspects further relate to utilizing laser temperature stabilisation techniques for use in a Raman spectrometer, for example portable Raman spectrometers which may be used in a handheld mode.

### BACKGROUND

Raman spectrometers are used to analyse a variety of samples by illuminating the sample with the light from a laser and analysing Raman scattered light resulting from excitation by the illumination light. A wide range of samples can be analysed by Raman spectroscopy including liquid, solids, and samples contained in packaging. Raman spectroscopy is a measurement technique that uses a laser beam to irradiate a sample.

### SUMMARY

According to one aspect of the present invention there is provided a system comprising a laser for illuminating a sample under investigation,

a temperature sensor for sensing the operating temperature of the laser and generating an output which is indicative of the sensed temperature,

a temperature stabilisation device for controlling the operating temperature of the laser, and

a controller for determining a target operating temperature or temperature range for the laser based on the output of the temperature sensor and for controlling the temperature stabilisation device to drive the operating temperature of the laser towards the target operating temperature or temperature range.

This arrangement allows the amount of power used in taking the laser to a desired temperature or temperature range to be minimised by allowing selection of a temperature which is preferable bearing in mind a starting temperature of the laser—which may, for example, be at or influenced by the temperature of the surroundings.

The system may comprise a spectrometer. The system may comprise a Raman spectrometer. The system may comprise a portable Raman spectrometer.

The controller may be arranged to determine a laser wavelength at which the laser will emit radiation when operating at the respective target operating temperature or at a temperature within the selected range.

The system may comprise a store holding a plurality of selectable operating temperatures or temperature ranges for the laser and the controller may be arranged for determining said target operating temperature or temperature range for the laser by selecting one of said plurality of selectable operating temperatures or temperature ranges.

The store may hold in association with each selectable operating temperature or temperature range in the plurality of selectable operating temperatures or temperature ranges, data which is indicative of a laser wavelength at which the laser will emit radiation when operating at the respective selectable operating temperature or at a temperature within the selected range.

Where the store holds at least one selectable temperature, the store may hold in association with each selectable operating temperature in the plurality of selectable operating temperatures, a value which is indicative of a laser wavelength at which the laser will emit radiation when operating at the respective selectable operating temperature.

Where the store holds at least one selectable temperature range, the store may hold in association with each selectable operating temperature range in the plurality of selectable operating temperatures ranges, calibration data which allows calculation from a temperature within the respective selectable operating temperature range of a value indicative of a laser wavelength at which the laser will emit radiation when operating at said temperature within the respective selectable operating temperature range.

This facilitates operation of the system with the laser at selected different operating temperatures in circumstances where the laser wavelength varies with temperature.

The system may be arranged for operating the laser at a plurality of selectable laser current levels.

The controller may be arranged for determining the target operating temperature or temperature range for the laser in dependence on the output of the temperature sensor and the laser current level to which the system is set.

The controller may be arranged to determine a laser wavelength at which the laser will emit radiation when operating at the respective selectable operating temperature or at a temperature within the selected range and with the laser current level at which the system is set.

The store may hold a respective plurality of selectable operating temperatures or temperature ranges for the laser at each laser current level in the plurality of selectable laser current levels.

The store may hold in association with each selectable operating temperature or temperature range in each plurality of selectable operating temperatures or temperature ranges, data which is indicative of a laser wavelength at which the laser will emit radiation when operating at:

i) the respective selectable operating temperature or at a temperature within the selected range; and

ii) at the respective current level.

The store may hold in association with each selectable operating temperature in each plurality of selectable operating temperatures, a value which is indicative of a laser wavelength at which the laser will emit radiation when operating at the respective selectable operating temperature and at the respective current level.

The store may hold in association with each selectable operating temperature range in the plurality of selectable operating temperatures ranges, calibration data which allows calculation, from a temperature within the respective selectable operating temperature range and the respective current level, of a value indicative of a laser wavelength at which the laser will emit radiation when operating at said temperature within the respective selectable operating temperature range and at the respective current level.

The store may hold a lookup table specifying a first plurality of selectable operating temperatures for a first laser current level and a second plurality of selectable operating temperatures for a second laser current level. The lookup table may further comprise a value which is indicative of a laser wavelength at which the laser will emit radiation when operating at the respective selectable operating temperature and at the respective current level.

The controller may be arranged to determine the target operating temperature by selecting a selectable operating temperature from the plurality of selectable operating temperatures which is closest to the temperature sensed by the temperature sensor.

The controller may be arranged to determine the target operating temperature by noting a laser current level to which the system is set and selecting a selectable operating temperature from the plurality of selectable operating temperatures or temperature ranges which is closest to the temperature sensed by the temperature sensor amongst those selectable operating temperatures which are associated with the laser current level to which the system is set.

The spectrometer may be arranged to use the laser wavelength determined by the controller in processing of Raman responses detected following illumination of a sample with the laser.

The spectrometer may comprise a detector for detecting Raman spectra emitted in response to illumination by the laser and may comprise illumination optics for directing the beam of the laser to the sample, and collection optics for collecting a Raman emission from the sample and directing this towards the detector.

The system may comprise an auto-focusing system for focusing the laser on the sample under investigation.

The system may comprise a screen for displaying information to a user. For example this screen may be an LCD screen and may for example display menu options for use in controlling the system and/or may display data concerning investigations made using the system.

The screen may be mounted for movement between a first position for use when the system is used in a first orientation and a second position for use when the system is used in a second orientation.

The first orientation may be an orientation where the sample is to be located below the system. The second orientation may be an orientation where the sample is to be located above the system.

The screen may be moveable between a state where it faces towards the same direction as the laser beam leaves the system in use and a state where it faces towards an opposite direction.

The screen may be hingedly mounted to a main body of the system.

The screen may be flush with the main body in one state and project from the main body in another state. Where the screen projects from the main body, the screen may help support the system in use.

The system may comprise a computer for controlling overall operation of the system. The controller may comprise the computer operating under control of software.

According to another aspect of the present invention there is provided a system comprising a laser for illuminating a sample under investigation,

a temperature sensor for sensing the operating temperature of the laser and generating an output which is indicative of the sensed temperature,

a temperature stabilisation device for controlling the operating temperature of the laser, and

a controller for determining a selected operating temperature for the laser, from a predetermined plurality of selectable operating temperatures, based on the output of the temperature sensor and for controlling the temperature stabilisation device to drive the operating temperature of the laser towards the selected operating temperature.

According to another aspect of the present invention there is provided a Raman spectrometer arrangement comprising:
a Raman spectrometer as defined above, and
a spectrometer accessory which is mountable on the spectrometer.

The spectrometer arrangement may comprise an interlock arrangement for controlling operation of the laser wherein the interlock arrangement enables operation of the laser when the accessory is mounted on the spectrometer and disables operation of the laser when the accessory is not mounted on the spectrometer.

According to another aspect of the present invention there is provided a method of generating lookup table for use with a system as defined above, the lookup table specifying a first plurality of selectable operating temperatures for a first laser current level and further comprising a value which is indicative of a laser wavelength at which the laser will emit radiation when operating at the respective selectable operating temperature and at the respective current level.

The lookup table may further specify a second plurality of selectable operating temperatures for a second laser current level and further comprise a value which is indicative of a laser wavelength at which the laser will emit radiation when operating at the respective selectable operating temperature and at the respective current level.

The method may comprise the steps of:

determining a respective plurality of selectable operating temperatures for a respective laser current level by:

a) operating the laser at the respective current level, driving the laser to a trial operating temperature and measuring at least one of the optical power and the wavelength of the laser at the trial operating temperature;

b) repeating step a) at a plurality of trial operating temperatures over a predetermined range;

c) plotting the at least one of the optical power and the wavelength of the laser against temperature from the results obtained by carrying out steps a) and b);

d) identifying discontinuities in the plots generated in step c);

e) selecting temperatures for the plurality of selectable operating temperatures which are away from temperatures corresponding to the discontinuities identified in step d).

The method may comprise the steps of:

defining a plurality of laser current levels for use in the system;

determining a respective plurality of selectable operating temperatures for each laser current level in the plurality of laser current levels by:

a) operating the laser at the respective current level, driving the laser to a trial operating temperature and measuring at least one of the optical power and the wavelength of the laser at the trial operating temperature;

b) repeating step a) at a plurality of trial operating temperatures over a predetermined range;

c) plotting the at least one of the optical power and the wavelength of the laser against temperature from the results obtained by carrying out steps a) and b);

d) identifying discontinuities in the plots generated in step c);

e) selecting temperatures for the plurality of selectable operating temperatures which are away from temperatures corresponding to the discontinuities identified in step d).

This allows identification of stable regions in the laser operation which are away from mode hops and thus facilitates selection of suitable selectable operating temperatures.

The method may comprise the step of selecting as selectable operating temperatures those temperatures which are midway between temperatures corresponding to adjacent discontinuities identified in the plots generated in step d).

The method may comprise the further step of determining the wavelength at each selectable operating temperature.

Each of the optional features following each of the aspects of the invention above can be equally applicable as an optional feature in respect of each of the other aspects of the invention and could be written after each aspect with any necessary changes in wording. The optional features are not written after each aspect merely in the interests of brevity.

### BRIEF DESCRIPTION OF DRAWINGS

Embodiments of the present invention will now be described, by way of example only, with reference to the accompanying drawings in which:

FIG. 1 schematically shows a portable Raman spectrometer;

FIG. 2 schematically shows components of the Raman spectrometer shown in

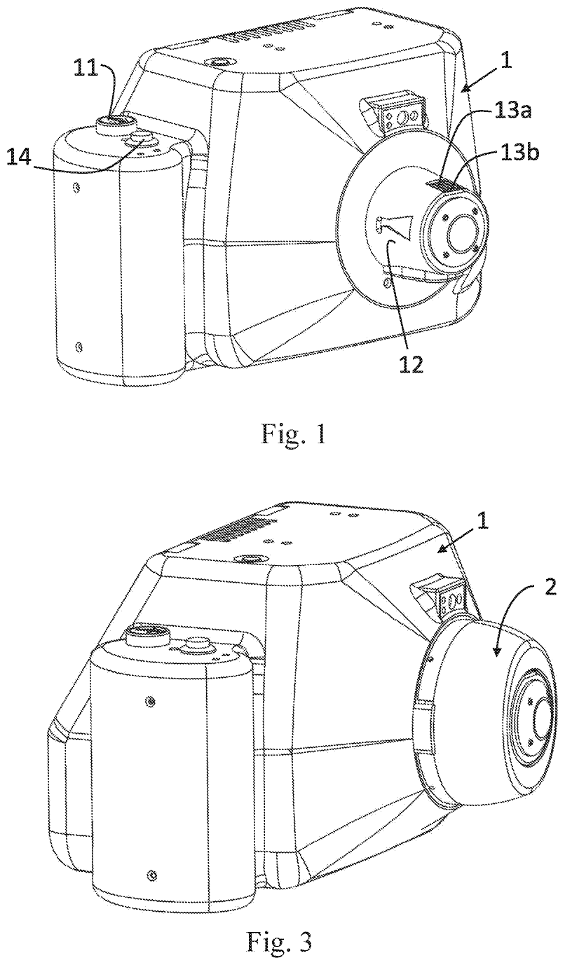

FIG. 1;

FIG. 3 shows the Raman spectrometer of FIG. 1 with a first accessory mounted on the spectrometer to form a spectrometer arrangement;

FIG. 4 shows a flow chart illustrating a process for stabilising the temperature of the laser which is followed by the spectrometer shown in FIGS. 1 to 3;

FIG. 5 shows a flow chart illustrating a process for determining suitable target operating temperatures for use in a process of the type shown in FIG. 4;

FIG. 6 is a plot of optical power of a laser plotted against operation temperature for three current levels;

FIG. 7 is a plot showing a derivative of a first of the plots shown in FIG. 6 representing use of the laser at a high current setting;

FIG. 8 is the plot of FIG. 7 including an indication of target operating temperatures selected for use;

FIG. 9 is a plot showing laser wavelength against temperature and an indication of target laser operation temperatures selected for use;

FIG. 10 shows a table of a type which may be stored in a spectrometer of the type shown in FIGS. 1 to 3 giving a plurality of target laser operating temperatures and laser wavelengths which result from operating the laser at a high, medium or low current level respectively at the respective operating temperatures.

### DETAILED DESCRIPTION

The applicant has recognized and appreciated that, when analysing samples using Raman spectroscopy, the quality of the analysis is affected by the wavelength stability of the laser. As an example, diode lasers that are conventionally wavelength stabilised by incorporation within an external cavity are useful for Raman spectroscopy because of their relatively good wavelength stability over a broad temperature range. In such an example, the wavelength is still somewhat dependent on the temperature of the cavity and the electrical current (or laser current) driving the laser. Additional issues with the analysis may result if the laser undergoes mode hops, which may occur at certain temperature/current settings, and the stability of both the output power and wavelength is poorer if the laser is operated in the region of one of these mode hops. It may, therefore, be beneficial to use some form of temperature stabilisation to increase the performance of such a system.

A conventional technique for wavelength stabilisation of a laser is to operate the laser at a constant temperature and current as far as possible away from a mode hop. However, a spectrometer may be used in situations with a wide range of temperatures (e.g., the environment in which the laser is used may vary in temperature) and/or the laser itself may be capable of operating at a wide range of temperatures. Thus in some circumstances when temperature stabilisation is to be carried out, the difference between an initial temperature of the device (e.g., based on the temperature of the environment in which the laser is being operated) and the constant temperature at which the device is arranged to operate may be large. The applicant has recognized and appreciated that, in such situations, a relatively large amount of power may be required to drive the temperature of the laser towards that constant temperature for operation. In some cases, this large power expenditure may become problematic. One example is in the case of a portable device where battery life may be reduced if a large amount of battery power is used to stabilise the temperature of the laser at a temperature far from the environmental temperature.

The applicant has therefore recognized and appreciated that an alternative approach is desirable. Accordingly, some embodiments are directed to techniques for stabilising the temperature of a laser that are based on the initial temperature of the laser itself. In some cases, this initial temperature may be based on the temperature of the environment in which the laser operates. It is noted that the present application focuses on particular examples of laser temperature stabilisation techniques for use in a Raman spectrometer. Embodiments are not limited to Raman spectrometers, however, as the laser temperature stabilisation techniques described herein may be used in any system that uses a laser.

FIG. 1 schematically shows a portable Raman spectrometer 1 which is arranged for carrying out Raman spectroscopy for a range of samples. This spectrometer 1 may be used in a number of different ways including in a hand-held mode.

The detailed functioning and operation of Raman spectrometers for use in Raman spectroscopy in the field of analysing samples is well known and this will not be described in detail here.

At a very general level in Raman spectroscopy a sample is illuminated with a highly focused laser of a suitable wavelength/frequency (for example a near infrared laser, though lasers with other emission spectra may be used). As a result of the illumination, some materials, particularly those materials with organic chemical components, will inelastically scatter the incident laser light in an interaction known as Raman scattering. The Raman scattered light can be collected and analysed, resulting in a Raman emission spectrum. The Raman emission spectrum includes wavelengths that are shifted from the wavelength of the illuminating laser. The shift in wavelength of the scattered light is caused by the laser radiation interacting with different virtual energy states, due to vibrational modes and other effects, that exist in the sample being investigated.

Photons from the laser illumination having a first energy are absorbed and emitted at a different energy following this interaction with the vibrational states and so on in the sample. The different photon energies correspond to different wavelengths/frequencies.

The resulting Raman emission spectrum that is obtained is characteristic of a particular material or materials that are present in the sample. Thus, by considering observed Raman spectra, one or more materials present in the sample can be identified. The Raman scattering effect is typically small resulting in a low signal-to-noise ratio, where a high noise level results from the illuminating radiation simply (elastically) scattering off the sample. Accordingly, a spectral filter is typically included in the Raman spectrometer to remove light at the illumination wavelength.

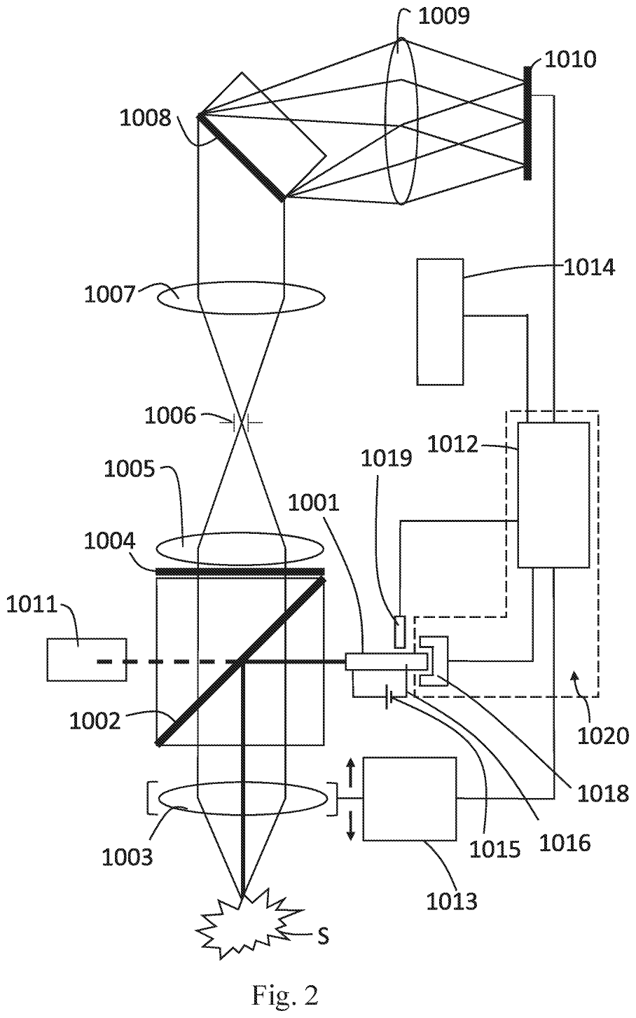

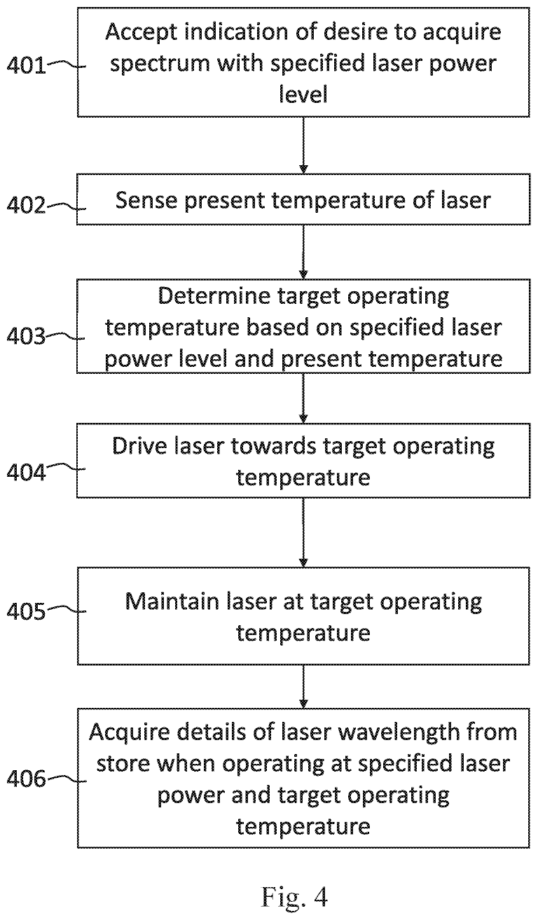

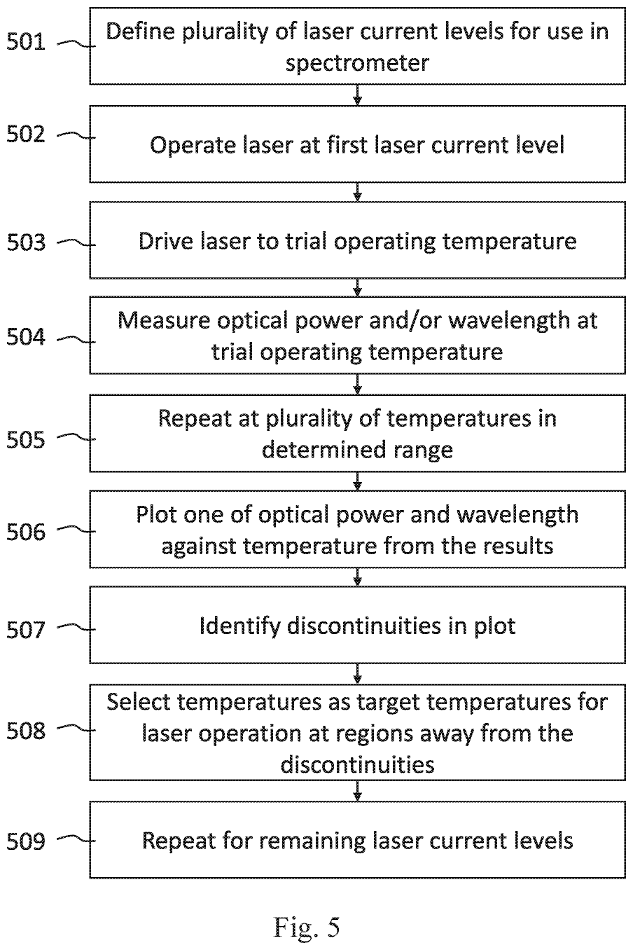

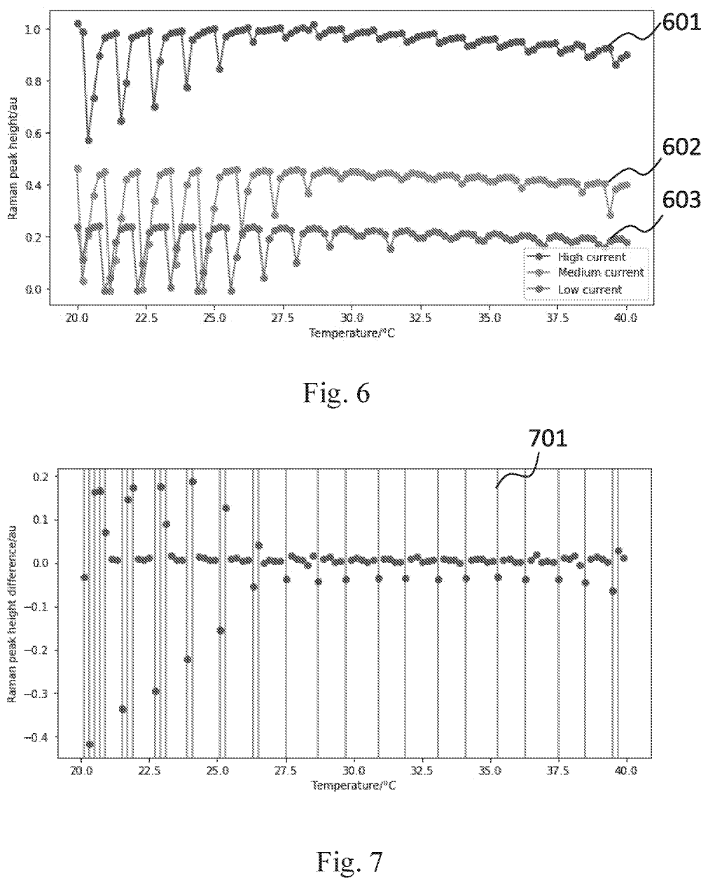

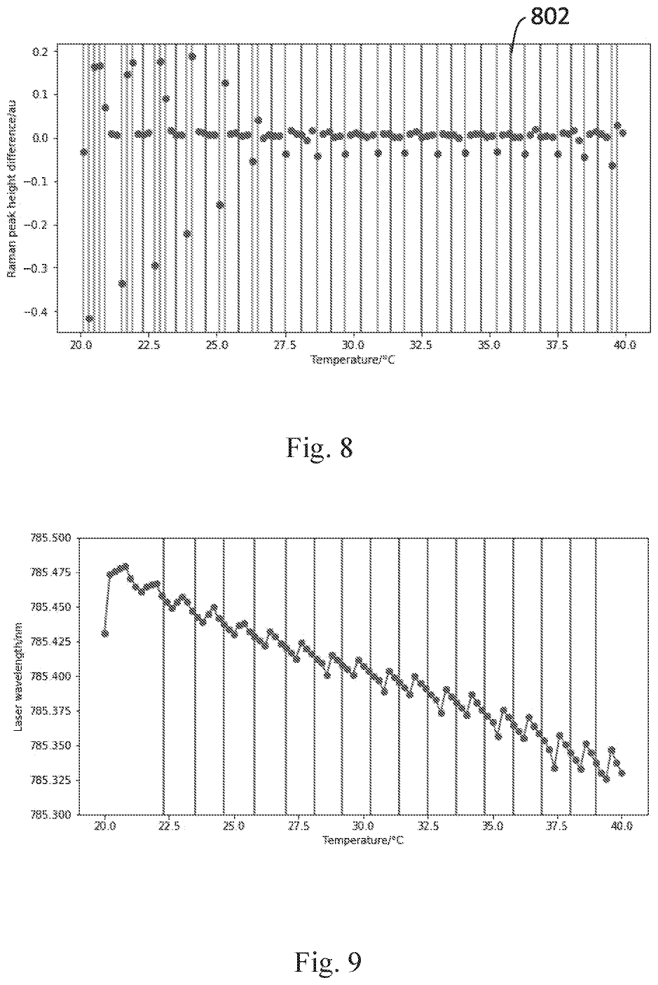

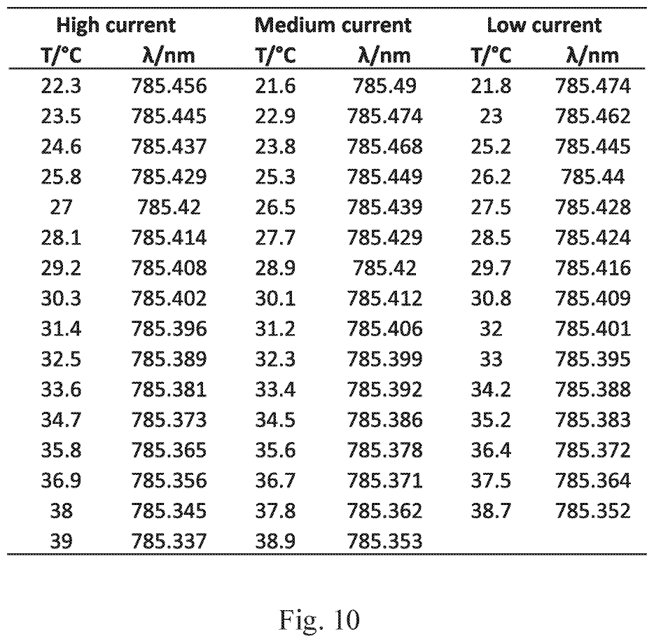

FIG. 2 schematically shows some of the internal components of the spectrometer shown in FIG. 1. The spectrometer 1 comprises a laser 1001 the beam of which is directed via a dichroic mirror 1002 through an objective lens 1003 to a sample S. This laser light (which in some embodiments is of a near infra-red frequency) interacts with the sample S and is scattered. Scattered radiation is collected by the objective lens 1003 and passes through the dichroic mirror 1002. This collected light then meets a Rayleigh filter 1004. In some embodiments, the Rayleigh filter 1004 may be a notch filter or a long-pass filter based on the wavelength of the laser and is provided to filter out light which has been elastically scattered by the sample rather than inelastically scattered. In other words, Raman scattered light is allowed to continue through the spectrometer 1 towards a detector 1001 while laser light is blocked by the filter 1004 and prevented from reaching the detector 1001.

The filtered light passes through a spectrometer coupling lens 1005 through the spectrometer entrance slit 1006 and is directed by a spectrometer collimating lens 1007 onto a diffraction grating 1008. The diffraction grating 1008 is arranged so that light of different wavelengths/frequencies will be diffracted at a different angle. Thus, the output of the diffraction grating 1008 suitably focused by a spectrometer focusing lens 1009 arrives on the detector of the spectrometer at a spatial position which is dependent on the wavelength of the light. In the embodiment illustrated in FIG. 2, the detector 1010 is a linear CCD array but other types of spatially resolving detectors may be used. Since the diffraction grating 1008 spatially separates the light based on wavelength, the detector 1010 can directly measure the spectrum of the Raman scattered light. The output from the detector 1010, which may include electrical signals, is provided to a controller 1012, which may be implemented as a computer under the control of software. The computer may comprise a processor, tangible non-transitory memory and a data storage device. The output may be stored and/or analysed by the controller 1012. The spectrometer 1 may also include a beam dump 1011 which absorbs any portion of the laser beam 1001 that passes through the dichroic mirror 1002.

The spectrometer 1 further comprises a focusing system 1013 including drive means, such as a translation stage, for driving the objective lens 1003 along its optical axis for focusing the laser beam on the sample S. The focusing system 1013 operates under the control of the controller 1012.

The spectrometer 1 may also include a user display screen 1014 that also operates under the control of the controller 1012. The display screen 1014 may show a visual indication of the output from the detector 1010. For example, a graph of the Raman spectrum of the sample S may be displayed. A variety of user options may also be displayed by the display screen 1014, such as options for controlling the operation of the focusing system 1013 and the laser 1001. Further the user display screen 1014 may be a touch screen device used for accepting user inputs to control operation of the spectrometer 1.

The user display screen 1014 is on the rear of the spectrometer as shown in FIGS. 1 and 3 and thus not visible in those views.

In some embodiments, the laser 1001 is a diode laser and caused to operate by a laser current provided from a power source 1015 via an electrical conduction path 1016. However, other types of lasers may be used, such as solid state, gas, or dye lasers, may be used. In some embodiments the power source 1015 comprises one or more battery.

In some embodiments, the spectrometer 1 is provided with at least two interlock mechanisms for preventing accidental operation of the laser 1001 and/or operation of the laser 1001 in unsafe circumstances. A first interlock mechanism comprises a key operated switch 11 provided on the spectrometer as shown in FIG. 1. This switch 11 is configured to cause a break in the electrical conduction path 1016 when in an off position such that operation of the laser 1001 is prevented without the key switch 11 turned to an on position by insertion of a suitable key. Thus, the first interlock mechanism controls an overall operation of the device.

In some embodiments, the spectrometer further comprises a temperature stabilisation device 1018 for use in controlling the temperature of the laser 1001 and a temperature sensor 1019 for sensing the temperature of the laser 1001. The temperature stabilisation device operates under the control of the central controller 1012 in response to an output from the temperature sensor 1019. Together the temperature stabilisation device 1018, the sensor 1019 and the controller 1012 can be considered to comprise a temperature stabilisation system 1020.

In some embodiments, the temperature stabilisation device 1018 comprises a thermoelectric device. The temperature stabilisation device 1018 may comprise a proportional-integral-derivative (PID) controller and a Peltier device (capable of heating and cooling the laser 1001) controlled by the PID controller. In turn the temperature stabilisation device 1018, and in particular the PID controller operates under the control of the central controller 1012. The temperature stabilisation device 1018 is also powered by the battery 1015.

The function and operation of the temperature stabilisation system 1020 is described in more detail further below.

In some embodiments, the spectrometer 1 may include an acquire spectrum button 14 which is depressable by a user when it is desired to acquire a spectrum, similar to a user taking a photograph with a camera. Depressing the button 14 will only cause operation of the laser 1001 and acquisition of a spectrum if the interlocks are all in the laser enabled state. In some embodiments, button 14 may be omitted and acquisition of the Raman spectrum may be initiated by the controller 1012 or by user input to the display screen 1014.

A second interlock mechanism, in some embodiments, may be provided in the form of interaction between the spectrometer 1 and a respective accessory 2 (as shown in FIG. 3) which is mountable on the spectrometer 1.

As shown in FIG. 1 the present spectrometer 1 comprises an accessory mounting portion 12 which, in some embodiments, is turret shaped. A pair of contacts 13a, 13b are provided on the accessory mounting portion 12. These contacts 13a and 13b are a part of the electrical conduction path 1016. Electrical current, e.g., the laser current, may flow from the power source 1015 to the laser 1001 when the first contact 13a is electrically connected to the second contact 13b, whereas when the contacts 13a, 13b are not connected to each other, the conduction path 1016 is interrupted and hence laser current flow is interrupted, thereby preventing the laser current from flowing and preventing operation of the laser 1001.

FIG. 3 shows a first accessory 2 mounted on the spectrometer 1. The first accessory 2 may be an interlock collar which is configured to allow operation of the spectrometer when the collar 2 is correctly fitted on the mounting portion 12. This is achieved because the collar 2 comprises an electrical conductor portion 21 which forms part of the conduction path 1016 for allowing powering of the laser 1001 when the collar 2 is correctly mounted on the spectrometer 1. The first accessory 2 is arranged so that, when correctly fitted, the conductor portion 21, connects the first contact 13a to the second contact 13b on the accessory mounting portion 12, thereby allowing the laser current to flow from the power source 1015 to the laser 1001.

Other accessories may be used with the spectrometer 1 but these are not described here as they are a subject of another invention and patent application. Similarly in alternatives the present invention may be embodied in a spectrometer of a different type that does not require a separate accessory to function. Such a spectrometer may again be a hand-held spectrometer.

Based on the foregoing, in some embodiments the spectrometer 1 cannot function without the accessory 2 in place, but with the accessory 2 in place the spectrometer 1 can function. This leads to an overall spectrometer arrangement shown in FIG. 3 which can be used in a hand-held mode such that the spectrometer arrangement may be taken to the location of a sample to be analysed, the spectrometer may be positioned in relation to the sample, and a spectrum may be acquired by a user operating the acquire spectrum button 14. In this hand-held mode, in response to the user pressing the button 14 to take a spectrum, the controller 1012 may control the focusing system 1013 to cause movement of the objective lens 1003 to automatically focus the laser beam onto the sample.

In the hand-held mode of operation, that is to say with the spectrometer arrangement shown in FIG. 3, whilst the presence of a collar 2 is required to allow the spectrometer 1 to operate, the accessory 2 does not provide any additional safety via shielding or obscuring of the laser beam. Thus, in the spectrometer arrangement as shown in FIG. 3, if the laser is a class IIIB laser, the overall spectrometer arrangement will also be a class IIIB device. Consequently, other safety precautions, training, and controlled areas etc, may be required when using the device in this configuration. However, these inconveniences are counteracted by the flexibility and convenience of being able to use the device in the hand-held mode. As mentioned above, different modes of operation and different types of spectrometer from a structural point of view may be used with the present invention.

As mentioned above, when using a Raman spectrometer for analysing samples it may be desirable for the wavelength at which the laser is emitting the illuminating radiation to be stable and also at a known wavelength. Further, lasers used in this type of spectrometer have a wavelength which is dependent on temperature. In some embodiments, the laser may be implemented as a hybrid external cavity diode laser. The temperature of the laser may be stabilised making use of the temperature stabilisation system 1020 comprising the temperature sensor 1019, the temperature stabilisation device 1018 and the controller 1012.

In some embodiments, the temperature sensor 1019 senses the operating temperature of the laser 1001, an output from the temperature sensor 1019 is fed to the central controller 1012, which in turn controls the temperature stabilisation device 1018 so as to drive the laser 1001 towards a target operating temperature. In some embodiments, the target operating temperature is a temperature at which the wavelength of the laser is known and also known to be stable. Further, in some embodiments, the target operating temperature is based on the current temperature of the laser 1001, such that the operating temperature may be different when the laser 1001 is operated in a hot environment versus a cold environment. Thus, when the laser is driven to this operating temperature, the spectrometer may make use of the known wavelength at which the laser will be emitting radiation in the analysis of the results which are acquired in the main operation of the Raman spectrometer.

In some embodiments, when a user desires to acquire a Raman spectrum of a sample, the user will first input into the spectrometer, for example via an option on the display screen 1014, a power level at which the laser should operate. When a user initiates the acquisition of a spectrum by operating the spectrum acquire button 14, the temperature stabilisation process begins.

FIG. 4 shows a flowchart of this process, according to some embodiments.

In box 401, the spectrometer accepts an indication of the desire to acquire a spectrum with a specified power level. In box 402, the spectrometer senses the present temperature of the laser 1001. For example, the present temperature may be the temperature of the environment of the laser if the laser has not recently been operated. In box 403, based on the specified power level and the present temperature gained from boxes 401 and 402, the spectrometer determines a target operating temperature for the laser 1001.

In box 404 the spectrometer drives the laser 1001 towards the target operating temperature by virtue of the central controller 1012 controlling the temperature stabilisation advice 1018 to apply the appropriate cooling and/or heating to the laser 1001.

Then in box 405 the temperature stabilisation system 1020, i.e. the central controller 1012 and temperature stabilisation device 1018, is used to maintain the laser at the target operating temperature.

It will be realised that, in some embodiments, the system maintains the laser at the target operating temperature within a tolerance which is acceptable for the operation of the system. In some cases, a temperature range might be specified rather than an absolute temperature.

In some embodiments, a storage device of the central controller 1012 stores details of the laser wavelength associated with each target operating temperature for each specified laser power and in step 406 the central controller 1012 can recover this wavelength information from the store and use it in the processing of spectra acquired by the detector 1010.

In alternative embodiments, rather than the storage device of the controller 1012 storing wavelength values, calibration data may be stored which enables calculation of the laser wavelength from other parameters such as the specified laser power and the target operating temperature. For example, the actual laser wavelength to be used in processing spectra may be determined by interpolating between points which are held in the system.

By following the above process the laser 1001 may be operated at a temperature which has been selected to give stable performance whilst minimising the amount of power used to stabilise the laser at that temperature by virtue of picking a target operating temperature for the laser which is based on the temperature of the laser detected in step 402.

In some embodiments, the spectrometer may hold, as a look up table, a table such as shown in FIG. 10 indicating a plurality of possible target operating temperatures for the laser at each of a number of specified laser power levels. In such a case in box 403, in determining the target operating temperature for the laser, the central controller 1012 may select that temperature appearing in the stored table which matches the specified laser power level and is closest in temperature to the temperature sensed by the sensor in box 402.

In such a case, if the sensor temperature is midway between two temperatures held in the table, the temperature above the sensor temperature may be selected in circumstances where heating the laser 1001 to a higher temperature is more energy efficient than cooling it to a lower temperature. Similarly in alternatives, the central controller 1012 may not be arranged to select the temperature which is necessarily the one closest to the sensed temperature but may make the determination on some other basis. For example it might be determined that the most energy efficient approach is to pick a temperature somewhere above the presently sensed temperature on the basis that as the device is operated the temperature will tend to increase.

However it will be understood in each case benefits are being derived since the target operating temperature for the laser 1001 is selected based on the output of the temperature sensor 1019 as well as other factors which may be taken into account.

FIGS. 5 to 9 below relate to a process which may be followed in determining suitable target operating temperatures for the laser 1001 at a plurality of different current levels. In the present example, three different current levels are considered—a high level, a medium level and a low level. Then for each current level, a number of target operating temperatures are determined for the laser representing temperatures where the laser is stable at the respective current level.

FIG. 5 is a flowchart of a process for determining a set of target operation temperatures and wavelengths such as shown in FIG. 10.

In box 501, a plurality of laser current levels for use in the spectrometer are determined. In box 502, the laser is operated at the first current level and in box 503 the laser is driven to a trial operating temperature.

In box 504 the optical power or wavelength of the laser is measured at the trial operating temperature.

In box 505 this is repeated at a plurality of temperatures in a defined range and in box 506 one of optical power or wavelength is plotted against temperature from the results of boxes 502 to 505. Then in box 507, discontinuities in the plot are identified. These discontinuities represent where behaviour of the laser is unstable. Typically these represent mode hops in the oscillation mode of laser 1001.

In box 508, temperatures as target temperatures for laser operation are selected at regions away from the discontinuities. Then in box 509, this process can be repeated for the remaining laser current levels to build up a complete table of the type shown in FIG. 10.

FIG. 6 shows an example of set of results for measuring optical power of a laser of the present type against operation temperature. FIG. 6 shows three traces, a first 601 representing results when a laser is operated at a high power setting, a second 602 showing results when the laser is operated at a medium setting and a third 603 showing results when the laser is operated at a low current setting. It will be appreciated that in this specification where the expressions high, medium and low current setting are used, these refer to the relationship between those settings—that is there would then be three setting with the first the highest of the three, the third the lowest setting and the second at some point between the first and the third.

In order to obtain these results, the laser optical power can be measured directly with a power meter or indirectly by measuring Raman scattering from a constant sample using a spectrometer. This may for example make use of a strongly Raman scattering liquid which is transparent at the laser wavelength. In the case of a 785 nm laser, using toluene as the sample works well. If Raman scattering is used, this has the advantage that the laser wavelength may be measured at the same time.

Note that in defining the temperature step, that is the spacing between trial temperatures, it is useful to ascertain the temperature range over which mode hops occur and then ensure that there are at least five data points per mode hop. In the present example, the temperature step was set to 0.2° C.

In making each measurement, the temperature of the laser was set and allowed to stabilise and then the power of the laser recorded. In the present example, the Raman scattering spectrum of toluene was recorded and the height of the peak at a Raman shift value near 1050 cm⁻¹ was taken as a proxy for laser power.

In considering FIG. 6, the discontinuities can be directly seen. However in order to determine these computationally it is helpful to take a derivative of the results. That is a measure of the difference between adjacent points. FIG. 7 shows a plot which gives such a derivative for the signal at the high current setting 601 from the plot shown in FIG. 6. Here a region of poor stability is indicated by a large absolute value of the derivative. A threshold for an instable region/discontinuity having been found can be set. In the present example the threshold of 0.025 was selected.

As a next step and as illustrated in FIG. 7, for each plot value where the derivative exceeds the threshold an instability (discontinuity) can be determined to have been found. These instabilities are indicated by lines 701 shown in FIG. 7.

In some cases there is a large area of instability, or instabilities are very close together. In order to reject such regions, regions are rejected where the spacing between adjacent instabilities is below a certain threshold. Where this test is passed, suitable target operation temperatures for the laser may be identified by locating the midpoint between adjacent discontinuities. These points are illustrated by lines 802 indicated in FIG. 8.

These then become the target operating temperatures which form the values to be included in a look-up table of the type shown in FIG. 10. It can be noted that the values shown by lines 802 in FIG. 8 correspond to the temperature values shown in the left-hand column in FIG. 10—that is the values for use of the laser at the high current level.

A similar process can be repeated for determining target operating temperatures for the laser at the medium current and low current levels.

In order to complete the table in FIG. 10, the wavelength at each selected temperature and current combination needs to be acquired. This may be done by directly measuring the output of the laser using a wavelength meter or indirectly from a Raman scattering measurement of a sample with a known peak location and using a spectrometer with a calibrated wavelength scale.

FIG. 9 shows a plot of laser wavelength against operating temperature at the high current level mentioned above. It will be noted that given such data even if a selected operating temperature for the laser does not coincide with one of the points for which a precise laser wavelength is known, the appropriate laser wavelength may be determined by interpolation from the data.

Once an appropriate set of data as indicated by the table shown in FIG. 10 has been determined, this may be loaded into the storage device in the spectrometer for use during operation.

Determination of such a look-up table for use with a spectrometer may be determined for a given type of laser which is then included in a number of spectrometers along with the associated look-up table. Alternatively each spectrometer may be calibrated using a process of the type described above. In some situations such a calibration may be carried out at the point of manufacture and may be repeated at later times to be sure accurate operation of the system. Note that the calibration does not require special equipment if the above mentioned method is used where a sample with a known Raman response is used. Then the spectrometer itself may be used in conjunction with the sample to determine appropriate stable temperatures at the different current levels for use as target operating temperatures and moreover the wavelength of the laser when operating at these temperatures may be determined by use of the spectrometer itself. This thus allows a convenient mechanism for recalibrating a spectrometer from time to time.

Having thus described several aspects of at least one embodiment of the present invention, it is to be appreciated that various alterations, modifications, and improvements will readily occur to those skilled in the art. Such alterations, modifications, and improvements are intended to be part of this application and are intended to be within the spirit and scope of the present invention. Further, though advantages of some embodiments are indicated, it should be appreciated that not every embodiment will include every described advantage. Some embodiments may not implement any features described as advantageous herein. Accordingly, the foregoing description and drawings are by way of example only. Some embodiments can be implemented in a number of ways. For example, some embodiments may be implements using hardware, software or a combination thereof. When implemented in software, the software code can be executed on any suitable processor or collection of processors. Such processors may be implemented as integrated circuits, with one or more processors in an integrated circuit component.

Various aspects of the above-described embodiments may be used alone, in combination, or in a variety of arrangements not specifically discussed in the described embodiments. Embodiments are therefore not limited in their application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another, but are used merely as labels to distinguish one claim element having a certain name from another element having a same name (but for use of the ordinal term) to distinguish the claim elements.

The indefinite articles “a” and “an,” as used herein in the specification and in the claims, unless clearly indicated to the contrary, should be understood to mean “at least one.”

The phrase “and/or” as used herein in the specification and in the claims, should be understood to mean “either or both” of the elements so conjoined, i.e., elements that are conjunctively present in some cases and disjunctively present in other cases.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. The transitional phrases “consisting of’ and “consisting essentially of’ shall be closed or semi-closed transitional phrases, respectively.

1. A system comprising:
a laser for illuminating a sample under investigation;
a temperature sensor for sensing the operating temperature of the laser and generating an output which is indicative of the sensed temperature;
a temperature stabilisation device for controlling the operating temperature of the laser; and
a controller for determining a target operating temperature or temperature range for the laser based on the output of the temperature sensor and for controlling the temperature stabilisation device to drive the operating temperature of the laser towards the target operating temperature or temperature range.

2. A system according to claim 1 in which the controller is arranged to determine a laser wavelength at which the laser will emit radiation when operating at the respective target operating temperature or at a temperature within the selected range.

3. A system according to claim 1 in which the system is arranged for operating the laser at a plurality of selectable laser current levels and the controller is arranged for determining the target operating temperature or temperature range for the laser in dependence on the output of the temperature sensor and the laser current level to which the system is set.

4. A system according to claim 3 in which the controller is arranged to determine a laser wavelength at which the laser will emit radiation when operating at the respective selectable operating temperature or at a temperature within the selected range and with the laser current level at which the system is set.

5. A system according to claim 1 in which the system comprises a store holding a plurality of selectable operating temperatures or temperature ranges for the laser and the controller is arranged for determining said target operating temperature or temperature range for the laser by selecting one of said plurality of selectable operating temperatures or temperature ranges.

6. A system according to claim 5 in which the store holds in association with each selectable operating temperature or temperature range in the plurality of selectable operating temperatures or temperature ranges, data which is indicative of a laser wavelength at which the laser will emit radiation when operating at the respective selectable operating temperature or at a temperature within the selected range.

7. A system according to claim 5 in which the system is arranged for operating the laser at a plurality of selectable laser current levels and the controller is arranged for determining the target operating temperature or temperature range for the laser in dependence on the output of the temperature sensor and the laser current level to which the system is set and the store holds a respective plurality of selectable operating temperatures or temperature ranges for the laser at each laser current level in the plurality of selectable laser current levels.

8. A system according claim 7 in which the store holds in association with each selectable operating temperature or temperature range in each plurality of selectable operating temperatures or temperature ranges, data which is indicative of a laser wavelength at which the laser will emit radiation when operating at:
i) the respective selectable operating temperature or at a temperature within the selected range; and
ii) at the respective current level.

9. A system according to claim 5 in which the store holds a lookup table specifying a first plurality of selectable operating temperatures for a first laser current level and a second plurality of selectable operating temperatures for a second laser current level and the lookup table further comprises a value which is indicative of a laser wavelength at which the laser will emit radiation when operating at the respective selectable operating temperature and at the respective current level.

10. A system according to claim 5 in which the controller is arranged to determine the target operating temperature by selecting a selectable operating temperature from the plurality of selectable operating temperatures which is closest to the temperature sensed by the temperature sensor.

11. A system according to claim 5 in which the system is arranged for operating the laser at a plurality of selectable laser current levels and the controller is arranged for determining the target operating temperature or temperature range for the laser in dependence on the output of the temperature sensor and the laser current level to which the system is set and the controller is arranged to determine the target operating temperature by noting a laser current level to which the system is set and selecting a selectable operating temperature from the plurality of selectable operating temperatures or temperature ranges which is closest to the temperature sensed by the temperature sensor amongst those selectable operating temperatures which are associated with the laser current level to which the system is set.

12. A system comprising a laser for illuminating a sample under investigation, a temperature sensor for sensing the operating temperature of the laser and generating an output which is indicative of the sensed temperature, a temperature stabilisation device for controlling the operating temperature of the laser, and
a controller for determining a selected operating temperature for the laser, from a predetermined plurality of selectable operating temperatures, based on the output of the temperature sensor and for controlling the temperature stabilisation device to drive the operating temperature of the laser towards the selected operating temperature.

13. A method of generating lookup table for use with a system according to claim 1, the lookup table specifying a first plurality of selectable operating temperatures for a first laser current level and further comprising a value which is indicative of a laser wavelength at which the laser will emit radiation when operating at the respective selectable operating temperature and at the first current level, and
the lookup table further specifying a second plurality of selectable operating temperatures for a second laser current level and further comprising a value which is indicative of a laser wavelength at which the laser will emit radiation when operating at the respective selectable operating temperature and at the second current level, wherein,
the method comprises the steps of:
defining the first and second laser current levels for use in the system; determining a respective plurality of selectable operating temperatures for the first laser current level and for the second laser current level for inclusion in the lookup table by:
a) operating the laser at the respective current level, driving the laser to a trial operating temperature and measuring at least one of the optical power and the wavelength of the laser at the trial operating temperature;
b) repeating step a) at a plurality of trial operating temperatures over a predetermined range;
c) plotting the at least one of the optical power and the wavelength of the laser against temperature from the results obtained by carrying out steps a) and b);
d) identifying discontinuities in the plots generated in step c);
e) selecting temperatures for the plurality of selectable operating temperatures which are away from temperatures corresponding to the discontinuities identified in step d).

14. A system according to claim 1, wherein the system is a Raman spectrometer.

15. A system according to claim 14, wherein the Raman spectrometer is portable.
